(19) United States
(12) Patent Application Publication
(10) Pub. No.: US 2007/0218699 A1
(43) Pub. Date: Sep. 20, 2007

(54) PLASMA ETCHING METHOD AND COMPUTER-READABLE STORAGE MEDIUM

(75) Inventor: Ryoichi YOSHIDA, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/686,686

(22) Filed: Mar. 15, 2007

Related U.S. Application Data
(60) Provisional application No. 60/785,997, filed on Mar. 27, 2006.

(30) Foreign Application Priority Data
Mar. 16, 2006 (JP) 2006-072825

(51) Int. Cl. H01L 21/467

(52) U.S. Cl. 438/710; 438/735

(57) ABSTRACT

In a plasma etching method for plasma-etching an etching stop film after plasma-etching a low-k film in a structure in which a wiring layer, the etching stop film made of an SiC-based material, the low-k film and an etching mask are formed in that order on a substrate, the method includes the step of arranging the structure having the plasma-etched low-k film in a processing chamber in which a first and a second electrode are provided to face each other at vertically separated locations. The plasma etching method further includes the steps of introducing a processing gas containing NF₃ into the processing chamber; generating a plasma by applying a high frequency power to one of the first and the second electrode; and applying a DC voltage to said one of the electrodes.

### FIELD OF THE INVENTION

The present invention relates to a plasma etching method and a computer-readable storage medium storing the plasma etching method, wherein the plasma etching method serves to plasma-etch an etching stop film after plasma-etching a low-k film in a structure where a wiring layer, the etching stop film made of an SiC-based material, the low-k film and an etching mask are formed in that order on a substrate.

### BACKGROUND OF THE INVENTION

A miniaturization of semiconductor devices reduces a distance between wirings and, therefore, an inter-wiring capacitance increases. Accordingly, a signal propagation speed is reduced, which in turn reduces an operating speed. To that end, there are being developed an interlayer insulating film made of an insulating material having a low dielectric constant (low-k material), i.e., a low-k film, and a multilayer interconnection using same. Meanwhile, copper having low resistance and high electromigration tolerance has been noticed as a wiring material. Further, a dual damascene method is often used to form a groove wiring and a contact hole for copper.

When the multilayer interconnection of copper is formed by using the dual damascene method, an etching stop film made of an SiC-based material, such as an SiCN film or the like, is formed on an underlying copper wiring. Next, a low-k film serving as an interlayer insulating film, a metal hard mask layer and an etching mask layer such as a photoresist film and the like are formed thereon in that order. Thereafter, a via is formed by etching the low-k film and, then, a trench etching is performed. Subsequently, the via is penetrated by etching the etching stop film and, then, a buried wiring layer is formed.

However, when the etching stop film is etched by using a conventional CF-based etching gas, it is difficult to obtain a sufficient selectivity with respect to the low-k film. This is because the etching stop film is similar in composition to those of the low-k film.

In order to solve the aforementioned problem, there has been suggested in Japanese Patent Laid-open Application No. 2005-302795 a technique for etching an SiC-based material by using an NF₃ gas at a high etching rate. Such a technique enables an etching stop layer made of an SiC-based film to be etched with a high selectively with respect to the low-k film.

However, when the etching stop layer made of the SiC-based film is etched by using the NF₃ gas, the etching is isotropically carried out. Therefore, an undercut in which the etching is performed in a horizontal direction is formed right under the low-k film.

### SUMMARY OF THE INVENTION

It is, therefore, an object of the present invention to provide a plasma etching method capable of etching an etching stop layer made of an SiC-based film positioned between a low-k film and a wiring layer with a desired etching selectivity with respect to the low-k film while preventing an undercut generation.

Further, it is another object of the present invention is to provide a computer-readable storage medium for storing therein a program for implementing such plasma etching method.

In accordance with one aspect of the invention, there is provided a plasma etching method for plasma-etching an etching stop film after plasma-etching a low-k film in a structure in which a wiring layer, the etching stop film made of an SiC-based material, the low-k film and an etching mask are formed in that order on a substrate, the method including the steps of: arranging the structure having the plasma-etched low-k film in a processing chamber in which a first and a second electrode are provided to face each other at vertically separated locations; introducing a processing gas containing NF₃ into the processing chamber; generating a plasma by applying a high frequency power to one of the first and the second electrode; and applying a DC voltage to said one of the electrodes.

In this case, an absolute value of the DC voltage is preferably greater than or equal to 400 V. Further, as for the low-k film, there may be employed an SiOC-based film. Furthermore, the DC voltage may have a previously obtained value by which a required etching shape was obtained in a test object. Moreover, the first and the second electrode are an upper and a lower electrode, respectively, and the high frequency power for plasma generation and the DC voltage may be applied to the first electrode. In this case, a high frequency power for ion attraction may be applied to the second electrode.

In accordance with another aspect of the invention, there is provided a computer readable storage medium for storing therein a computer-executable control program, wherein the control program, when executed in a computer, controls a plasma processing apparatus to perform the plasma etching method.

In accordance with the present invention, a plasma etching is performed on an etching stop film after plasma-etching a low-k film in a structure where a wiring layer, the etching stop film made of an SiC-based material, the low-k film and an etching mask are formed in that order on a substrate. To plasma-etch the etching stop film, a processing gas containing an NF₃ is introduced into a processing chamber while supplying a high frequency power for plasma generation to a first or a second electrode to generate a plasma. Moreover, by applying a DC voltage to any one of the electrodes, deposits are formed on an etching sidewall to thereby protect the sidewall and, further, electrons generated during the plasma formation are accelerated in a vertical direction in a processing space due to the DC voltage. Therefore, the etching can be carried out more anisotropically, which prevents a formation of an undercut. Furthermore, since the NF₃ gas having a substantially high selectivity with respect to the low-k film is used as an etching gas, a sufficient etching selectivity can be obtained even when an etching rate of the etching stop film deteriorates due to the deposits.

### BRIEF DESCRIPTION OF THE DRAWINGS

The above and other objects and features of the present invention will become apparent from the following description of embodiments, given in conjunction with the accompanying drawings, in which:

FIG. 1 is a schematic cross sectional view of an example of a plasma etching apparatus utilized in implementing the present invention;

FIG. 2 shows a matching unit connected to a first high-frequency power supply in the plasma etching apparatus shown in FIG. 1;

FIG. 3 illustrates a cross sectional view illustrating a structure of a semiconductor wafer W used in implementing a first embodiment of the present invention;

FIG. 4 presents a schematic view showing a state in which an undercut is formed in etching an etching stop film;

FIG. 5 represents a diagram illustrating changes in V_{dc} and thickness of a plasma sheath when a direct current voltage has been applied to an upper electrode in the plasma etching apparatus shown in FIG. 1;

FIG. 6 provides comparative plots respectively representing plasma states in case when the direct current voltage is applied to the upper electrode and in case when no direct current voltage is applied thereto in the plasma etching apparatus shown in FIG. 1;

FIG. 7 depicts a schematic diagram showing a state in which the etching stop film is etched by the embodiment of the present invention.

FIG. 8 offers a diagram describing a structure of a sample used for examining actual effects of a method of the present invention;

FIG. 9 describes a diagram illustrating a state in which a trench etching is performed on the sample of FIG. 8;

FIG. 10 shows a schematic diagram depicting a state in which the etching stop film is etched without applying a DC voltage to the upper electrode;

FIG. 11 describes a schematic diagram illustrating a state in which the etching stop film is etched by applying a DC voltage of −400 V to the upper electrode;

FIG. 12 provides a schematic diagram showing a state in which the etching stop film is etched by applying a DC voltage of −800 V to the upper electrode;

FIG. 13 represents a schematic diagram of an example of another plasma etching apparatus that can be employed for implementing the present invention;

FIG. 14 offers a cross sectional view showing another example of a plasma etching apparatus that can be employed in implementing the present invention;

FIG. 15 presents a schematic diagram showing a further example of a plasma etching apparatus that can be employed in implementing the present invention; and

FIG. 16 offers a cross sectional view showing a still further example of a plasma etching apparatus that can be employed in implementing the present invention;

### DETAILED DESCRIPTION OF THE EMBODIMENT

Hereinafter, embodiments of the present invention will be described in detail with reference to the accompanying drawings.

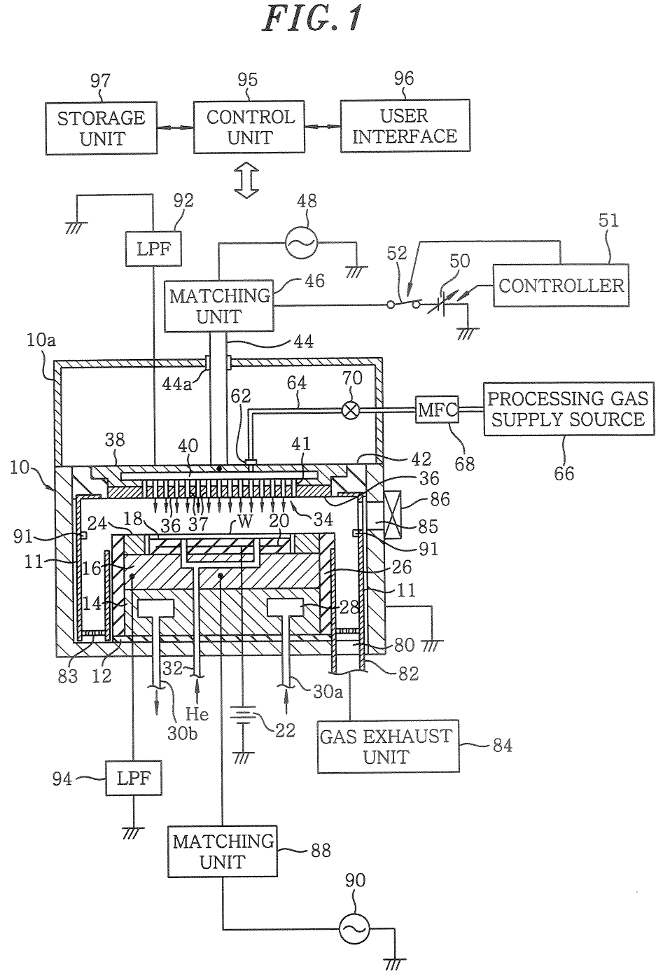

FIG. 1 is a schematic cross sectional view of an example of a plasma etching apparatus utilized in implementing the present invention.

This plasma etching apparatus is a capacitance-coupled parallel plate type plasma etching apparatus and includes a substantially cylindrical chamber (processing chamber) 10 made of, e.g. surface-anodized aluminum. The chamber 10 is a frame-grounded.

On a bottom portion of the chamber 10, there is arranged a cylindrical susceptor support 14 through an insulating plate 12 made of ceramics or other materials. A susceptor 16 made of, e.g., aluminum, is provided on the susceptor support 14, wherein the susceptor 16 is adapted to serve also as a lower electrode. A semiconductor wafer W serving as an object substrate is mounted on the susceptor (lower electrode) 16.

On a top surface of the susceptor 16, there is provided an electrostatic chuck 18 that attracts and holds the semiconductor wafer W with an electrostatic force. The electrostatic chuck 18 is of a structure having an electrode 20 made of a conductive film and interlaid between a pair of insulating layers or insulating sheets. A direct current power supply 22 is electrically connected to the electrode 20. The semiconductor wafer W is attracted to and held in place on the electrostatic chuck 18 by virtue of an electrostatic force, such as the Coulomb force, generated by a direct current voltage supplied from the direct current power supply 22.

On the top surface of the susceptor 16 around the electrostatic chuck 18 (or the semiconductor wafer W), there is arranged a conductive focus ring (calibration ring) 24 that is made of, e.g., silicon, and serves to improve an etching uniformity. A cylindrical inner wall member 26 made of, e.g., quartz, is provided on the outer surface of the susceptor 16 and the susceptor support 14.

A coolant chamber 28 is formed within the susceptor support 14 to extend, e.g., annularly along a circumferential direction. Coolant, e.g., cooling water, of a specific temperature is supplied to the coolant chamber 28 from an external chiller unit (not shown) to be circulated therein through pipelines 30a and 30b. The temperature at which the semiconductor wafer W on the susceptor 16 is treated can be controlled based on the temperature of the coolant.

Furthermore, a heat-conductive gas, e.g., an He gas, is supplied from a heat-conductive gas supply mechanism (not shown) to a space formed between a top surface of the electrostatic chuck 18 and a back surface of the semiconductor wafer W through a gas supply line 32.

Above the lower electrode or susceptor 16, there is provided an upper electrode 34 in a parallel and mutually facing relationship with the susceptor 16. Thus, the space formed between the upper electrode 34 and the lower electrode 16 becomes a plasma generation space. The upper electrode 34 is adapted to face the semiconductor wafer W on the lower electrode or susceptor 16, thereby forming a surface contiguous to the plasma generation space, i.e., an facing surface.

The upper electrode 34 is supported on an upper portion of the chamber 10 through an insulating shield member 42 and is constructed from an electrode plate 36 and a water-cooled electrode support body 38. The electrode plate 36 forms a surface facing the susceptor 16 and has a plurality of ejection ports 37. The electrode support body 38 is adapted to detachably support the electrode plate 36 and is made of a conductive material, e.g., surface-anodized aluminum. The electrode plate 36 is preferably formed of a conductive body with a small Joule heat and a low resistance or a semiconductor. From a standpoint of reinforcing a resist as set forth below, it is preferable that the electrode plate 36 is formed of a silicon-containing material. Thus, the electrode plate 36 is preferably made of silicon or SiC. Inside the electrode support body 38, there is provided a gas diffusion chamber 40 from which a multiple number of gas passage holes 41 extend in a downward direction to communicate with gas injection openings 37.

The electrode support body 38 has a gas inlet port 62 through which a processing gas is led to the gas diffusion chamber 40. Connected to the gas inlet port 62 is a gas supply line 64 which in turn is associated with a processing gas supply source 66. A mass flow controller (MFC) 68 and an opening/closing valve 70 are provided on the gas supply line 64 in the named sequence from the upstream side (an FCS (Flow Control System) may be used in place of the MFC). The processing gas for an etching operation, e.g., a fluorocarbon gas (CₓF_{y}) such as a CF₄ gas, is supplied to the gas diffusion chamber 40 from the processing gas supply source 66 through the gas supply line 64 and then is ejected into the plasma generation space in the form of a shower through the gas passage holes 41 and the gas injection openings 37. Namely, the upper electrode 34 serves to function also as a shower head for supplying the processing gas.

A first high-frequency power supply 48 is electrically connected to the upper electrode 34 via a matching unit 46 and a power supply rod 44. The first high-frequency power supply 48 is adapted to generate a high frequency power with a frequency of 10 MHz or higher, e.g., 60 MHz. The matching unit 46 serves to match a load impedance to an internal (output) impedance of the first high-frequency power supply 48 and functions to ensure that the apparent output impedance of the first high-frequency power supply 48 coincide with the apparent load impedance while plasma is being generated within the chamber 10. The matching unit 46 has an output terminal connected to a top end of the power supply rod 44.

In the meantime, a variable direct current power supply 50 as well as the first high-frequency power supply 48 is electrically connected to the upper electrode 34. The variable direct current power supply 50 may be a bipolar power supply. More specifically, the variable direct current power supply 50 is connected to the upper electrode 34 via the matching unit 46 and the power supply rod 44, and the power supply operation of the variable direct current power supply 50 is turned on or off by means of an on-off switch 52. A controller 51 is employed to control the polarity, current and voltage of the variable direct current power supply 50 and the on-off operation of the on-off switch 52.

Referring to FIG. 2, the matching unit 46 includes a first variable capacitor 54 branched from a power supply line 49 of the first high-frequency power supply 48 and a second variable capacitor 56 provided on the power supply line 49 downstream of the branching point of the first variable capacitor 54, both of which cooperate to perform the function noted above. In order to assure effective supply of an electric current of direct current voltage (hereinbelow simply referred to as “direct current voltage”) to the upper electrode 34, the matching unit 46 further includes a filter 58 for trapping the high frequency (of, e.g., 60 MHz) from the first high-frequency power supply 48 and the high frequency (of, e.g., 2 MHz) from a below-mentioned second high-frequency power supply. In other words, a direct current is supplied from the variable direct current power supply 50 to the power supply line 49 via the filter 58. The filter 58 includes a coil 59 and a capacitor 60, both of which serve to trap the high frequency from the first high-frequency power supply 48 and the high frequency from the below-mentioned second high-frequency power supply.

A cylindrical grounding conductor 10a is provided to extend from the sidewall of the chamber 10 more upwardly than the elevation of the upper electrode 34. The cylindrical grounding conductor 10a has a ceiling wall portion electrically insulated from the power supply rod 44 by virtue of an insulating member 44a.

A second high-frequency power supply 90 is electrically connected to the lower electrode or susceptor 16 through a matching unit 88. As a high frequency power is supplied from the second high-frequency power supply 90 to the lower electrode or susceptor 16, ions are introduced toward the semiconductor wafer W. The second high-frequency power supply 90 is adapted to generate a high frequency power whose frequency is in the range between 300 kHz and 13.56 MHz, e.g., 2 MHz. The matching unit 88 serves to match a load impedance to an internal (output) impedance of the second high-frequency power supply 90 and functions to ensure that the output impedance of the second high-frequency power supply 90 coincides with the apparent load impedance while plasma is being generated within the chamber 10.

Electrically connected to the upper electrode 34 is a low-pass filter (LPF) 92 not allowing the high frequency (60 MHz) supplied from the first high-frequency power supply 48 from passing thereto while allowing the high frequency (2 MHz) supplied from the second high-frequency power supply 90 to pass to the ground. Although the low-pass filter 92 is preferably formed of an LR filter or an LC filter, use of a single conductor line may suffice because it would be able to apply a great enough reactance against the high frequency (60 MHz) supplied from the first high-frequency power supply 48. On the other hand, a high-pass filter (HPF) 94 for passing the high frequency (60 MHz) supplied from the first high-frequency power supply 48 to the ground is electrically connected to the lower electrode or susceptor 16.

A gas exhaust port 80 is provided on the bottom portion of the chamber 10 and a gas exhaust unit 84 is connected to the gas exhaust port 80 through a gas exhaust line 82. The gas exhaust unit 84 is provided with a vacuum pump such as a turbo molecular pump and is capable of depressurizing the inside of the chamber 10 to a desired level of vacuum. A loading/unloading port 85 through which the semiconductor wafer W is conveyed into or out of the chamber 10 is formed on the sidewall of the chamber 10. The loading/unloading port 85 is openably closed by means of a gate valve 86.

A deposition shield 11 for preventing etching byproducts (depositions) from adhering to the chamber 10 is detachably provided along an inner wall of the chamber 10. That is to say, the deposition shield 11 forms a chamber wall. Another deposition shield 11 is provided on an outer circumference of the inner wall member 26. An exhaust plate 83 is provided near the lower portion of the chamber 10 between the deposition shield 11 closer to the chamber wall and the deposition shield 11 closer to the inner wall member 26. The deposition shields 11 and the exhaust plate 83 are preferably made of an aluminum material coated with ceramics such as Y₂O₃.

A conductive member (GND block) 91 grounded in a DC-like manner is provided on a portion of the deposition shield 11 for forming the chamber wall substantially at the same elevation as that of the semiconductor wafer W. This provides an advantageous effect that an abnormal electric discharge can be avoided.

Individual component parts of the plasma etching apparatus are configured such that they can be connected to and controlled by a control unit (general control device) 95 Also connected to the control unit 95 is a user interface 96 that includes, among other things, a keyboard for enabling a process manager to input commands to thereby manage the plasma etching apparatus and a display for visually displaying operating status of the plasma etching apparatus.

Additionally connected to the control unit 95 is a storage unit 97 that stores a control program for performing various processes executed by the plasma etching apparatus under a control of the control unit 95 and a program, i.e., recipes, for making the individual component parts of the plasma etching apparatus perform their tasks in accordance with given process conditions. The recipes may be stored in a hard disk or a semiconductor memory or may be set into a specific position of the storage unit 97 in a state recorded on a portable and computer-readable storage medium such as a CD-ROM, a DVD or the like.

If necessary, an arbitrary recipe is retrieved from the storage unit 97 by a command inputted through the user interface 96 and is then executed by the control unit 95, thus ensuring that a desired process is performed in the plasma etching apparatus under a control of the control unit 95.

Next, description will be made on the plasma etching method in accordance with a first embodiment of the present invention, which is implemented by means of the plasma etching apparatus of the above configuration.

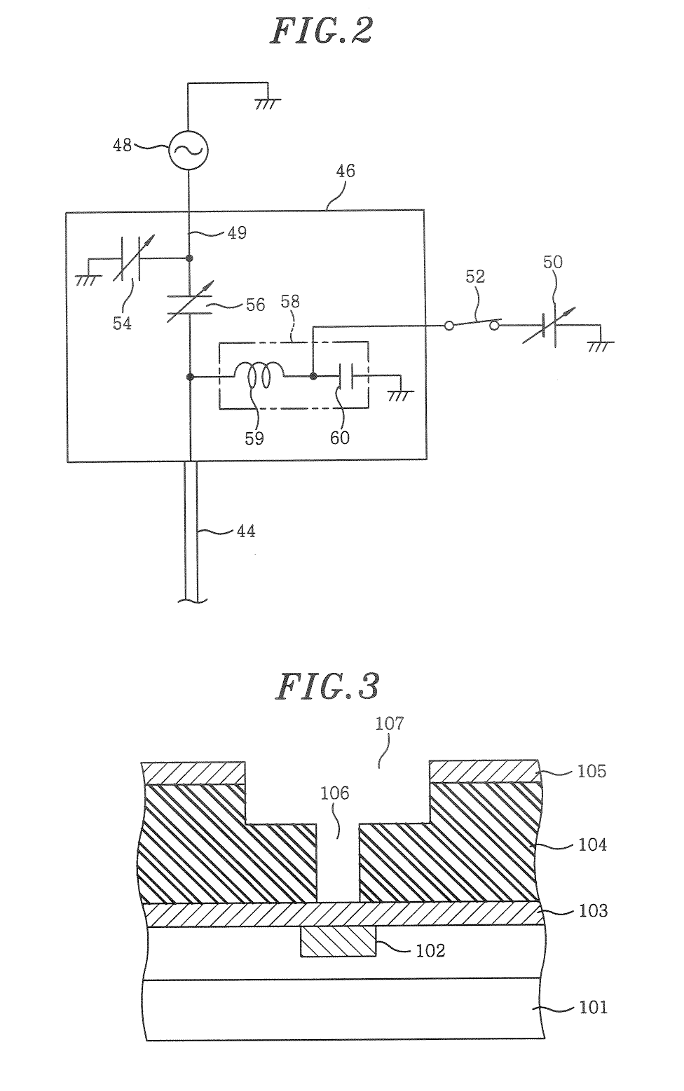

As shown in FIG. 3, as for a semiconductor wafer W serving as a target object, there is used one in which a copper wiring layer 102, an etching stop film 103, a low-k film 104 serving as an interlayer insulating film and a metal hard mask layer 105 are formed in that order on an Si substrate 101. Next, a via 106 is formed in the low-k film 104 by using an etching mask such as a photoresist film (not shown) or the like and, then, the etching mask is removed by an ashing. Thereafter, a trench 107 is formed by using the metal hard mask layer 105 as an etching mask.

The etching stop film 103 serving as an etching target film in this embodiment is made of an SiC-based material such as SiCN or the like, and a thickness thereof ranges between about 20 nm and about 100 nm. Further, as for the low-k film 104, an SiOC-based film is suggested as an example. The SiOC-based film is obtained by introducing a methyl group (—CH₃) to an Si—O bonding in a conventional SiO₂ film to obtain a mixture of Si—O and Si—CH₃ bondings. As for a material of the Low-k film 104, there may be used both a dense material and a porous material, such as Black Diamond (trademark of Applied Materials, Inc.), Coral (trademark of Novellus Systems Inc.), Aurora (trademark of ASM International N.V.) and the like. Although those materials are formed by a CVD process, there may be used a porous MSQ (Porous methyl-hydrogen-SilsesQuioxane) formed by an SOD (silicon on dielectric) process. A thickness of the low-k film 104 ranges between about 250 nm and 370 nm. As for a material forming the metal hard mask layer 105, TiN is suggested as an example, and a thickness thereof ranges between about 15 nm and about 45 nm.

First of all, while the gate valve 86 is opened, the semiconductor wafer W of the structure stated above is conveyed into the chamber 10 through the loading/unloading port 85 to be mounted on the susceptor 16, wherein the gate valve 86 is closed thereafter. Then, the processing gas for etching the etching stop film 103 is supplied to the gas diffusion chamber 40 from the processing gas supply source 66 at a specific flow rate. The processing gas is fed into the chamber 10 through the gas passage holes 41 and the gas injection openings 37, while the chamber 10 is evacuated by means of the gas exhaust unit 84 so that the inner pressure of the chamber 10 is set within the range of, e.g., about 2.7 Pa and about 200 Pa. Further, a temperature of the susceptor is set between about 20° C. and about 50° C., e.g., about 40° C. and a wafer temperature is set between about 20° C. and about 100° C., e.g., about 60° C.

As for a processing gas for etching the etching stop film 103 made of an SiC-based material, there is used one containing NF₃. As for the processing gas containing NF₃, there may be used a single NF₃ gas, a gaseous mixture of NF₃ gas and a rare gas such as Ar gas, He gas or the like, a gaseous mixture of NF₃ gas and CF₄ gas, a gaseous mixture of NF₃ gas, CF₄ gas and a rare gas such as Ar gas or the like, a gaseous mixture of NF₃ gas, Ar gas and CO gas, or the like. A flow rate of NF₃ gas is preferably between about 5 mL/min and about 50 mL/min (converted flow rate in standard state (scam)).

Under the condition that the etching gas is introduced into the chamber 10 in this manner, the first high-frequency power supply 48 is made to apply a high frequency power for plasma generation to the upper electrode 34 at a specific intensity and, at the same time, the second high-frequency power supply 90 is made to apply a high frequency power for ion attraction to the lower electrode or susceptor 16 at a prescribed intensity. A given direct current voltage is applied to the upper electrode 34 by means of the variable direct current power supply 50. Furthermore, a direct current voltage for the electrostatic chuck 18 is applied to the electrode 20 of the electrostatic chuck 18 from the direct current power supply 22, thereby fixing the semiconductor wafer W to the susceptor 16.

The processing gas ejected through the gas injection openings 37 of the electrode plate 36 of the upper electrode 34 is converted to a plasma in the midst of glow discharge generated between the upper electrode 34 and the lower electrode or susceptor 16 by the high frequency power. The etching stop film 103 of the semiconductor wafer W is etched with radicals or ions generated by the plasma.

Inasmuch as an electric power of high frequency band (e.g., 10 MHz or more) is supplied to the upper electrode 34, it becomes possible to increase the density of the plasma in a desired state, which in turn makes it possible to form a high density plasma even under a lower pressure condition.

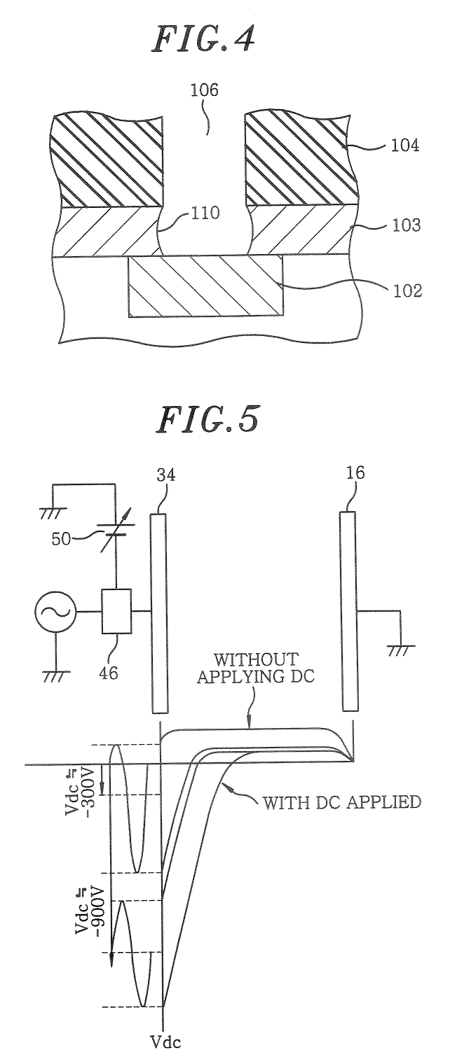

In case the etching stop film made of an SiC-based material such as SiCN or the like is etched by using a processing gas containing NF₃ while exclusively applying a high frequency power to the upper electrode 34, an etching can be performed with a high selectivity to the low-k film. However, the etching is carried out isotropically, so that an undercut 110 shown in FIG. 4 is generated. The occurrence of the undercut causes a poor wiring buriability and a wiring resistance variation.

Therefore, when the plasma is formed, a DC voltage of a specific polarity and value is applied from the variable DC power supply 50 to the upper electrode 34 in this embodiment. By controlling this application voltage, the etching stop film 103 can be etched in a good etching shape.

Hereinafter, this will be described in detail.

A polymer has been adhered to the upper electrode 34 by a previous etching process, especially by an etching process performed while supplying a small high-frequency power to the upper electrode 34. Further, when a desired DC voltage is applied to the upper electrode 34 in performing an etching process, it is possible to enlarge a self-bias voltage V_{dc} of the upper electrode, as illustrated in FIG. 5. In other words, an absolute value of V_{dc} on a surface of the upper electrode 34 can be increased. Accordingly, the polymer adhered to the upper electrode is sputtered by the applied DC voltage and then supplied to the semiconductor wafer W. The polymer is adhered to a sidewall of the etching stop film 103 as an etching target film and thus protects the sidewall of the etching stop film 103. As a result, it is difficult to etch the side wall of the etching stop film 103.

Further, when a DC voltage is applied to the upper electrode 34 in etching the etching stop film 103, electrons generated near the upper electrode 34 by the plasma are accelerated in a vertical direction in a processing space. At this time, the electrons can reach into the via by preferably controlling the DC voltage and the like. Hence, a shading effect is suppressed, resulting in a good processed shape without bowing.

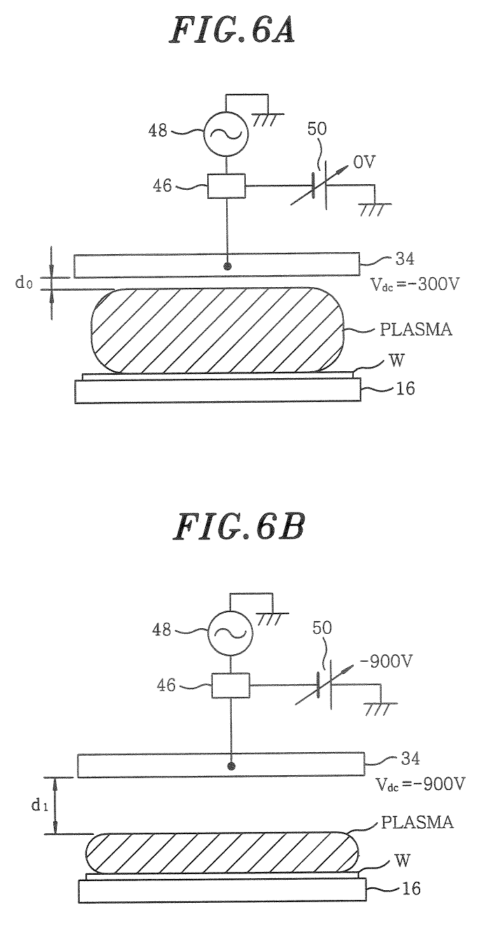

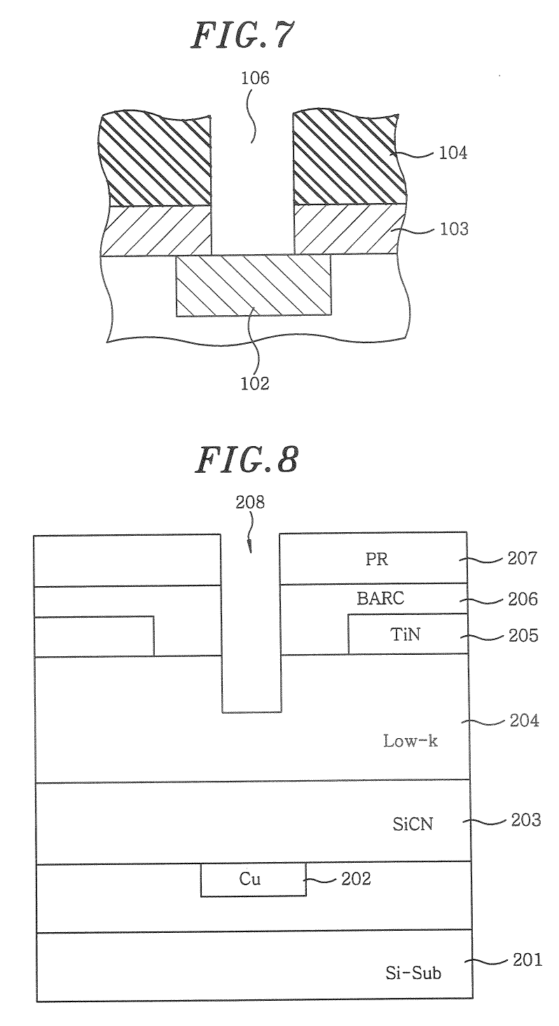

As shown in FIG. 5, increment of V_{dc} indicates an increase of a plasma sheath thickness. As the plasma sheath thickness increases, the plasma is pressed by that much. For example, when no DC voltage is applied to the upper electrode 34, V_{dc} Of the upper electrode side becomes about −300 V. In this case, the plasma sheath has a small thickness d₀, as shown in FIG. 6A. However, when a DC voltage of −900 V is applied to the upper electrode 34, V_{dc} of the upper electrode side becomes about −900 V. Since the plasma sheath thickness is in proportion to ¾ of an absolute value of V_{dc}, the plasma sheath has a larger thickness d₁, and the plasma is pressed by that much, as shown in FIG. 6B. Such a shift of a plasma causes a change in a bias power level, so that an etching anisotropy may be increased.

Due to the three effects described above, the etching stop film 103 made of an SiC-based material can be etched in a good etching shape without an undercut. At this time, an etching rate of the etching stop film 103 deteriorates by an operation of the polymer and, further, an etching selectivity to the low-k film 104 also deteriorates slightly However, since NF₃ gas having a substantially high selectivity to the low-k film is used as an etching gas, a desired selectivity of about 2 can be obtained. To do so, it is preferable that an absolute value of the DC voltage applied to the upper electrode 34 is greater than or equal to 400 V.

When performing the plasma etching method of the present embodiment, the first task is to etch a test semiconductor wafer under given conditions by use of the plasma etching apparatus shown in FIG. 1. Thereafter, the semiconductor wafer is conveyed out of the plasma etching apparatus and is inspected by means of an inspection apparatus to thereby find, in advance, a direct current voltage value capable of ensuring an etching selectivity and obtaining a desired shape without an undercut in etching the etching stop film. If an etching operation is carried out while applying a direct current voltage of the value thus found to the upper electrode, it is possible to rapidly perform the etching treatment under appropriate conditions. As the test semiconductor wafer noted above, a first single sheet or first two or more sheets of wafer in a particular wafer lot can be used.

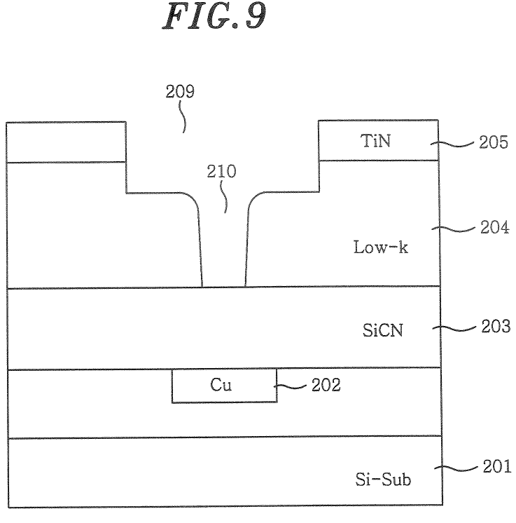

Hereinafter, a result of examining actual effects of the method of the present invention will be described. As illustrated in FIG. 8, a copper wiring layer 202, an etching stop film 203 made of SiCN having a thickness of about 35 nm to about 50 nm, a low-k film 204 made of an SiOC-based material having a thickness of about 250 nm to about 370 nm, a hard mask layer 205 having a thickness of about 30 nm and being made of TiN, the hard mask layer 205 being patterned for trench etching, a bottom anti-reflection coating (BARC) 206 and a photoresist film (PR) 207 are formed in that order on an Si substrate 201. Next, the BARC 206 and the low-k film 204 are etched to an intermediate depth of the low-k film 204 by using the PR film 207 as an etching mask, thus forming a sample having a partial via 208. After the PR film 207 and the BARC 206 are removed by an ashing, a plasma etching is performed by the apparatus of FIG. 1 while using the hard mask layer 205 as an etching mask, thereby forming a trench 209 shown in FIG. 9. During the etching process, the partial via 208 is also etched, thus forming a via 210 reaching the etching stop film 203. The etching was performed under following conditions;

Pressure: 13.3 Pa (100 mTorr)

RF power (upper 60 MHz/lower 2 MHz): 30 W/250 W

DC voltage: −400 V

Processing gas
CF₄ gas: 112 mL/min (sccm)
Ar gas: 150 mL/min (sccm)
O₂ gas: 6 mL/min (sccm)
C₄F₈ gas: 13 mL/min (sccm)

Time: 110 sec

Temperature susceptor: 40° C.
Wafer: 60° C.

Next, the etching stop film 203 was etched while applying a DC voltage to the upper electrode under three different conditions A, B and C respectively being 0 V, −400 V and −800 V in addition to following conditions;

Pressure: 6.0 Pa (45 mTorr)

RF power (upper 60 MHz/lower 2 MHz): 400 W/1000 W

DC voltage: 0 V

Processing gas
NF₃ gas: 12 mL/min (sccm)
Ar gas: 200 mL/min (sccm)
He gas: 240 mL/min (sccm)

Time: 15 sec

Temperature susceptor: 40° C.
Wafer: 60° C.

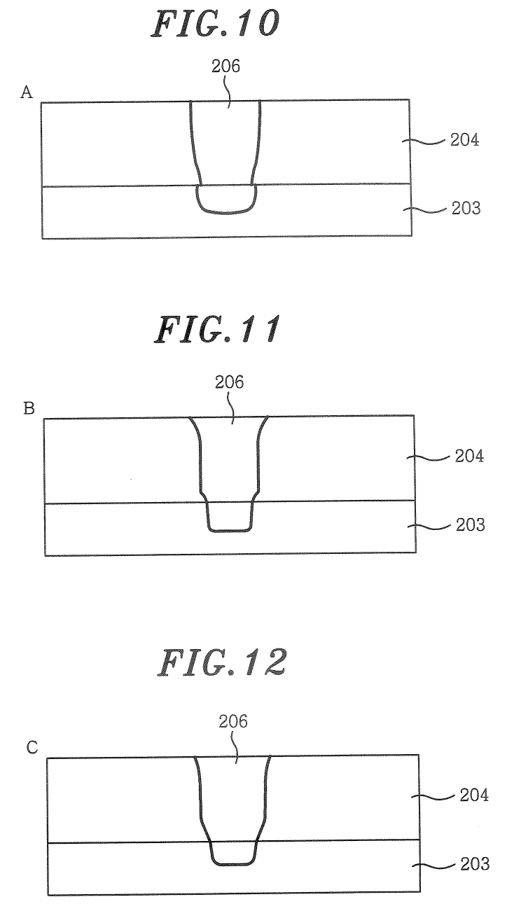

As a consequence, when no DC voltage was applied under the condition A, an etching width of 82 nm was actually obtained regardless of a designed etching width of 65 nm. Accordingly, an undercut shown in FIG. 10 was generated.

On the other hand, when the DC voltages was applied under the conditions B and C, no undercut was generated as shown in FIGS. 11 and 12. An etching width of 63 nm and that of 52 nm were obtained under the conditions B and C, respectively. In other words, an increase in an absolute value of the DC voltage enhances the effect of preventing a formation of an undercut.

Further, etching rates of the low-k film and the SiCN etching stop film were 40 nm/min and 160 nm/min under the condition A; 20 nm/min and 68 nm/min under the condition B; and 20 nm/min and 48 nm/min under the condition C. That is, as the absolute value of the DC voltage increases, the etching rate tends to decrease. Moreover, the selectivity of the etching stop film to the low-k film which was calculated based on the aforementioned etching rates was 4.0 under the condition A, 3.4 under the condition B and 2.4 under the condition C. In other words, although an increase in the absolute value of the DC voltage leads to a decrease in the selectivity, the selectivity greater than or equal to 2 can be obtained with the use of NF₃ gas.

As described above, by applying a DC voltage to the upper electrode 34 in plasma etching the SiC-based etching stop film with the use of a gas containing NF₃, the etching can be carried out without an undercut generation while maintaining a relatively high selectivity.

Moreover, the present invention can be variously modified without being limited to the aforementioned embodiments. For example, although the etching stop film was made of SiCN in the aforementioned embodiments, it can be made of SiC. Further, the present invention is not limited to the aforementioned application in which an SiC-based etching stop film is etched after forming a trench with respect to a via formed in advance in the low-k film.

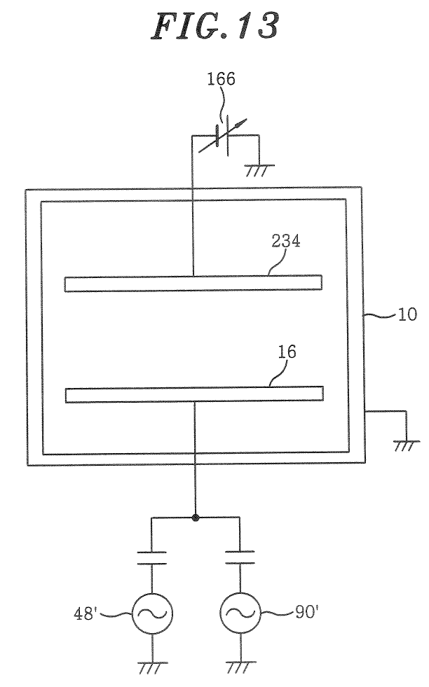

Furthermore, the apparatus for implementing the present invention is not limited to the one shown in FIG. 1. Alternatively, it may be possible to use a variety of other apparatuses as set forth below. For instance, it is possible to employ a plasma etching apparatus of the type applying two kinds of frequencies to a lower electrode as shown in FIG. 13, in which a high frequency power of, e.g., 60 MHz, for plasma generation is applied to the lower electrode from a first high-frequency power supply 48′ and a high frequency power of, e.g., 2 MHz, for ion attraction is applied to the lower electrode from a second high-frequency power supply 90′. The same advantageous effects as in the foregoing embodiments can be obtained by connecting a variable direct current power supply 166 to an upper electrode 234 and applying a given direct current voltage thereto as illustrated in FIG. 13.

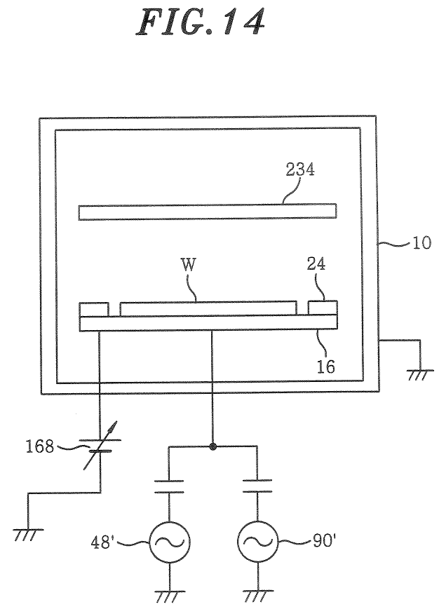

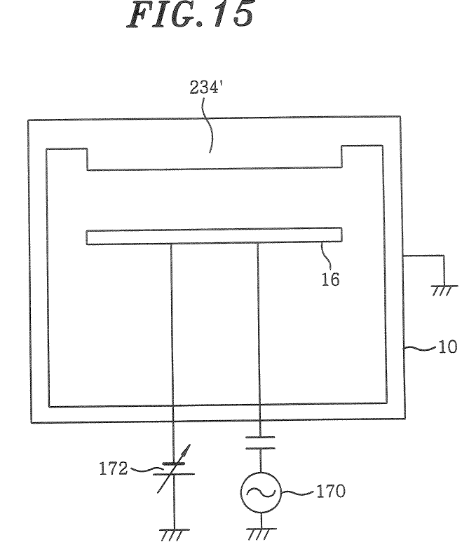

In this case, it may be possible that, as shown in FIG. 14, a direct current power supply 168 is connected to the lower electrode or susceptor 16 to thereby apply a direct current voltage to the susceptor 16.

Moreover, it is possible to employ a plasma etching apparatus of the type as shown in FIG. 15, wherein an upper electrode 234′ is grounded via the chamber 10 and a high-frequency power supply 170 is connected to the lower electrode or susceptor 16 so that the high-frequency power supply 170 can apply a high frequency power of, e.g., 13.56 MHz, for plasma generation. In this case, the same advantageous effects as in the foregoing embodiments can be obtained by connecting a variable direct current power supply 172 to the lower electrode or susceptor 16 and applying a given direct current voltage thereto as illustrated in FIG. 15.

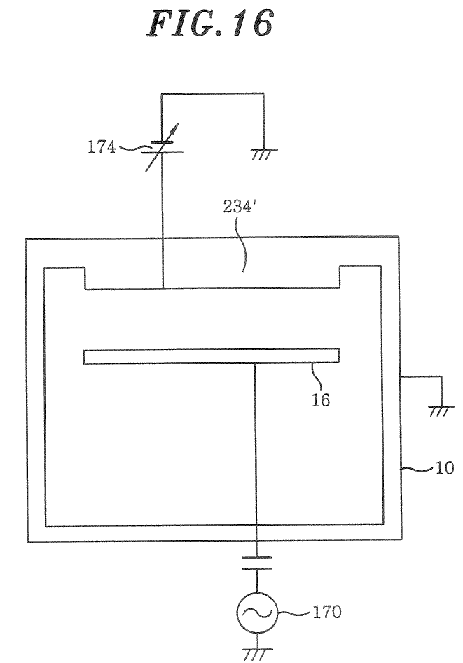

Alternatively, as illustrated in FIG. 16, a variable direct current power supply 174 may be connected to the upper electrode 234′ in the same plasma etching apparatus as shown in FIG. 15, wherein the upper electrode 234′ is grounded via the chamber 10 and the high-frequency power supply 170 is connected to the lower electrode or susceptor 16 so that the high-frequency power supply 170 can apply a high frequency power for plasma generation.

While the invention has been shown and described with respect to the preferred embodiments, it will be understood by those skilled in the art that various changes and modification may be made without departing from the scope of the invention as defined in the following claims.

What is claimed is:

1. A plasma etching method for plasma-etching an etching stop film after plasma-etching a low-k film in a structure in which a wiring layer, the etching stop film made of an SiC-based material, the low-k film and an etching mask are formed in that order on a substrate, the method comprising the steps of:
arranging the structure having the plasma-etched low-k film in a processing chamber in which a first and a second electrode are provided to face each other at vertically separated locations;
introducing a processing gas containing NF₃ into the processing chamber;
generating a plasma by applying a high frequency power to one of the first and the second electrode; and
applying a DC voltage to said one of the electrodes.

2. The plasma etching method of claim 1, wherein an absolute value of the DC voltage is greater than or equal to 400 V.

3. The plasma etching method of claim 1, wherein the low-k film is an SiOC-based film.

4. The plasma etching method of claim 2, wherein the low-k film is an SiOC-based film.

5. The plasma etching method of claim 1, wherein the DC voltage is a previously obtained value by which a required etching shape was obtained in a test object.

6. The plasma etching method of claim 2, wherein the DC voltage is a previously obtained value by which a required etching shape was obtained in a test object.

7. The plasma etching method of claim 1, wherein the first and the second electrode are an upper and a lower electrode, respectively, and the high frequency power for plasma generation and the DC voltage are applied to the first electrode.

8. The plasma etching method of claim 2, wherein the first and the second electrode are an upper and a lower electrode, respectively, and the high frequency power for plasma generation and the DC voltage are applied to the first electrode.

9. The plasma etching method of claim 5, wherein the first and the second electrode are an upper and a lower electrode, respectively, and the high frequency power for plasma generation and the DC voltage are applied to the first electrode.

10. The plasma etching method of claim 6, wherein the first and the second electrode are an upper and a lower electrode, respectively, and the high frequency power for plasma generation and the DC voltage are applied to the first electrode.

11. The plasma etching method of claim 7, wherein a high frequency power for ion attraction is applied to the second electrode.

12. The plasma etching method of claim 8, wherein a high frequency power for ion attraction is applied to the second electrode.

13. The plasma etching method of claim 9, wherein a high frequency power for ion attraction is applied to the second electrode.

14. The plasma etching method of claim 10, wherein a high frequency power for ion attraction is applied to the second electrode.

15. A computer readable storage medium for storing therein a computer-executable control program, wherein the control program, when executed in a computer, controls a plasma processing apparatus to perform the plasma etching method described in claim 1.

16. A computer readable storage medium for storing therein a computer-executable control program, wherein the control program, when executed in a computer, controls a plasma processing apparatus to perform the plasma etching method described in claim 2.

17. A computer readable storage medium for storing therein a computer-executable control program, wherein the control program, when executed in a computer, controls a plasma processing apparatus to perform the plasma etching method described in claim 3.

18. A computer readable storage medium for storing therein a computer-executable control program, wherein the control program, when executed in a computer, controls a plasma processing apparatus to perform the plasma etching method described in claim 5.

19. A computer readable storage medium for storing therein a computer-executable control program, wherein the control program, when executed in a computer, controls a plasma processing apparatus to perform the plasma etching method described in claim 7.

20. A computer readable storage medium for storing therein a computer-executable control program, wherein the control program, when executed in a computer, controls a plasma processing apparatus to perform the plasma etching method described in claim 11.
